(19) United States
(12) Patent Application Publication
(10) Pub. No.: US 2009/0135578 A1
(43) Pub. Date: May 28, 2009

(54) MAGNETIC SHIELDING FOR HIGH FIELD MAGNET

(76) Inventors: Michael John Disney Mallett, Wellington (NZ); Jeremy Francis Williams, Witney Oxon (GB)

Correspondence Address: SCHIFF HARDIN, LLP;PATENT DEPARTMENT, 6600 SEARS TOWER, CHICAGO, IL, 60606-6473, US

(21) Appl. No.: 12/271,097

(22) Filed: Nov. 14, 2008

(30) Foreign Application Priority Data
Nov. 15, 2007 (GB) 0722439.7

(51) Int. Cl. H05K 9/00

(52) U.S. Cl. 361/816

(57) ABSTRACT

Magnetic shielding for surrounding a magnet generating a magnetic field of maximum magnetic flux density substantially in excess of 5 Gauss, so as to reduce the magnetic flux density outside the shielding to no more than 5 Gauss wherein at least part of the shielding is composed of sheets of grain-oriented steel.

### BACKGROUND OF THE INVENTION

1. Field of the Invention

The present invention relates to magnets producing high magnetic fields, such as fields having a magnetic flux density B in excess of 1.5 Tesla. The present invention particularly relates to the shielding of magnets used in magnetic resonance imaging (MRI) equipment. More especially, although not exclusively, the present invention relates to shielding of mobile magnets, those carried in lorries or trailers, and still more especially to mobile magnets which are intended to be transported at field.

2. Description of the Prior Art

While magnetic resonance imaging (MRI) has become a well established medical imaging technique, installed at many locations around the world, a recent trend towards mobile MRI apparatus has emerged. Mobile MRI systems are typically contained in trucks or trailers and are moved between locations, so as to offer a temporary MRI facility to hospitals or towns which do not have the need for, or resources to fund, a permanently sited MRI system.

An essential part of an MRI system is the magnet. Such magnets produce strong magnetic fields Current mobile MRI systems use magnets which produce a magnetic field having a magnetic flux density of up to 1.5 T. However, it is desired to provide mobile MRI systems using magnets producing stronger magnetic fields, for example having a magnetic flux density of up to 3.0 T, since it is believed that such magnets will enable the production of improved images.

Superconducting magnets are often employed as the magnet in present MRI systems. As is well known to those skilled in the art, a superconducting magnet typically consists of several coils of superconducting wire within a cryostat. The cryostat is provided with a refrigerator and/or liquid cryogen which holds the coils at a temperature at which superconductivity is possible. When it is desired to bring the magnet into operation, current is gradually introduced into the coils, a process known as ramping up, by connecting a DC power source to the coils. This procedure takes time, and the heat which is inevitably produced within the cryostat may lead to consumption of liquid cryogen. As the coils are superconducting, the current will continue to flow through the coils even when the current source is removed. A magnetic field is produced. When it is desired to stop current flowing through the coils, and to remove the magnetic field, the DC power source is reconnected to the coils in a direction to oppose the current flowing in the coils. The current flowing decreases gradually until no more current flows. The DC power source is then removed. This process is known as ramping down.

Regarding magnets in mobile MRI systems, it would be convenient to transport the magnet at field—that is, with current flowing through its coils producing a magnetic field—between sites. This would avoid the need for time-consuming and possibly costly ramping up of the magnet at each new location, and ramping down when the magnet is due to move on to the next location.

Steps must be taken to prevent unnecessary exposure of persons to a stray magnetic field of the MRI magnet. While the magnet may produce a functional magnetic field having a magnetic flux density of 3 T, the extent of the 5 Gauss (5×10⁻⁴ T) contour of magnetic flux density represents the limit of magnetic field to which persons unconnected with the MRI operation may be exposed. Magnetic fields in excess of this strength may damage sensitive equipment, and represent a danger to persons using heart pacemakers, as operation of a pacemaker may be upset by magnetic flux densities greater than 5 Gauss (5×10⁻⁴ T). It is therefore common in permanently sited MRI systems to place the MRI magnet in a room sufficiently large to contain the 5 Gauss contour, and to exclude sensitive equipment and persons unrelated to operation of the MRI system from the room. In recent years, magnets have come into use which provide greater and greater magnetic flux densities. With the increase in maximum magnetic flux densities, the extent of the 5 Gauss (5×10⁻⁴ T) contour has expanded. In many instances, it is not practical to dedicate a room the size of the 5 Gauss (5×10⁻⁴ T) contour to housing the MRI system. Accordingly, it is common practice to provide magnetic shielding to contain the 5 Gauss (5×10⁻⁴ T) contour within a reasonable space. An exclusion zone may be established, which is lined with iron or steel sheets to a sufficient thickness and in an appropriate distribution to hold the 5 Gauss (5×10⁻⁴ T) contour within the exclusion zone, while sensitive equipment and persons are forbidden to enter the exclusion zone.

In a mobile MRI system, it becomes even more important to reduce the size of the 5 Gauss (5×10⁻⁴ T) contour, since the exclusion zone is typically limited to the size of the trailer or truck containing the magnet. The trailer or truck is typically much smaller than the size of an unshielded 5 Gauss (5×10⁻⁴ T) contour. It is therefore common to use large amounts of iron or steel shielding to restrict the extent of the 5 Gauss (5×10⁻⁴ T) contour to within the truck or trailer. With existing MRI magnets providing magnetic flux densities of up to 1.5 T, it has been found possible to achieve adequate shielding without increasing the weight of the truck or trailer above a maximum weight limit imposed by the design of the truck or trailer, or by regulations governing road transport.

FIG. 1 illustrates an arrangement of iron or steel shielding which is currently used to provide shielding of 1.5 T MRI magnets, such that the 5 Gauss (5×10⁻⁴ T) contour remains within the truck or trailer housing the magnet, at least to a height of 2.4 m above the ground. As can be seen in FIG. 1, numerous pieces of sheet iron or steel are used, which overlap and are of different sizes, more shielding being concentrated on walls of the truck or trailer which are close to the magnet, since the magnetic flux density of the stray field will be greater in these regions.

The magnetic induction, also known as magnetic flux density, B, is related to the magnetic field strength H, by the relationship B=μH, where μ is the permeability of the medium in question. In ferromagnetic materials, the permeability varies with magnetic field strength.

The basic principles of a magnetic shield can be understood from the observation that, for most of the shielding, the magnetic field strength H, and the magnetic induction B, inside the iron or steel of the shield is aligned parallel to the faces of the iron or steel sheets. At an outer surface of the shield, the magnetic field strength H, inside the material of the shield must equal the magnetic field strength in adjacent air which must be such that Bₐᵢᵣ=Hₐᵢᵣμ₀≦5×10⁻⁴ T. This corresponds to a magnetic field strength of H≦397 A·m⁻¹ (SI units) or H≦5 Oersteds (cgs units). The shield must also return an amount of flux Φ which is predominantly generated by the magnet. This amount of flux is in first approximation not affected by the shielding. The amount of flux inside the shield is proportional to the product of the thickness of the material of the shield and the magnetic induction B inside the steel.

Sheet steel currently used for such magnetic shielding is typically a non-grain-oriented, low carbon, silicon steel. This has isotropic, homogeneous behavior in a magnetic field, as will be discussed further below with reference to FIG. 3. The typically-used steel is relatively inexpensive, and is effective at shielding magnetic fields of high magnetic flux density B, but is less effective at shielding magnetic fields of low magnetic flux density, such as 5 Gauss (5×10⁻⁴ T). It is therefore necessary to provide a large amount of shielding steel to adequately shield the stray field, because at a certain thickness, the required magnetic induction B to contain the return flux, will drive the working point on the B-H curve to a value for H which is higher than 5 Oersteds (397 A·m⁻¹), the limit for effective shielding, as explained above.

Alternative arrangements have been used, for example in establishing a monitored exclusion zone outside of the truck or trailer once it has arrived on site, ramping up the magnet once the exclusion zone is in place, and ramping the magnet down again before the exclusion zone is removed and the truck or trailer moved. Such arrangements have obvious disadvantages, for example in that time, energy and cryogen may be consumed in the ramp up and ramp down procedures, which may only be performed while the magnet is on site and the exclusion zone is in position. The exclusion zone must be continuously monitored, for example by a security guard, to prevent intrusion by persons or equipment, and such arrangement does not address the desire to be able to transport the magnet at field, that is, with current flowing in the coils.

It has been found difficult to adequately shield a truck or trailer which houses a magnet generating a magnetic field with a magnetic flux density of 3 T, because such a magnet produces a higher amount of flux outside the boundaries of the trailer. To contain the extra amount of flux at the same magnetic field strength further iron or steel shielding is required to Such additional shielding increases the weight of the shield, and may cause the MRI system as a whole to exceed the permitted weight limit for the truck or trailer. It has accordingly been found that shielding a high field (>3 T magnetic flux density) superconducting magnet adequately for use in a mobile MRI system typically requires an unreasonably large mass of iron or steel shielding.

### SUMMARY OF THE INVENTION

An object of the present invention to provide an improved shielding arrangement for containing a magnetic field, which will enable a high field magnet to be transported at field in a mobile MRI system.

The present invention also aims to achieve adequate magnetic shielding within weight limits imposed by local regulations on maximum permitted load per axle and at a reasonable expenditure.

The above object is achieved in accordance with the present invention by magnetic shielding for surrounding a magnet that generates a magnetic field of a maximum magnetic flux density substantially in excess of 5 Gauss to reduce the magnetic flux density outside the shielding to no more than 5 Gauss, wherein a portion of the shielding is composed of sheets of grain-oriented steel, and a portion of the shielding is composed of sheets on non-grain-oriented steel, with layers of the sheets of non-grain-oriented steel being located in regions of relatively high magnetic flux density, and wherein only layers of the sheets of grain-oriented steel are located in regions of relatively low magnetic flux density.

### DESCRIPTION OF THE DRAWINGS

FIG. 1 illustrates a known screening arrangement for containing the stray field of a magnet used in a mobile MRI system; and

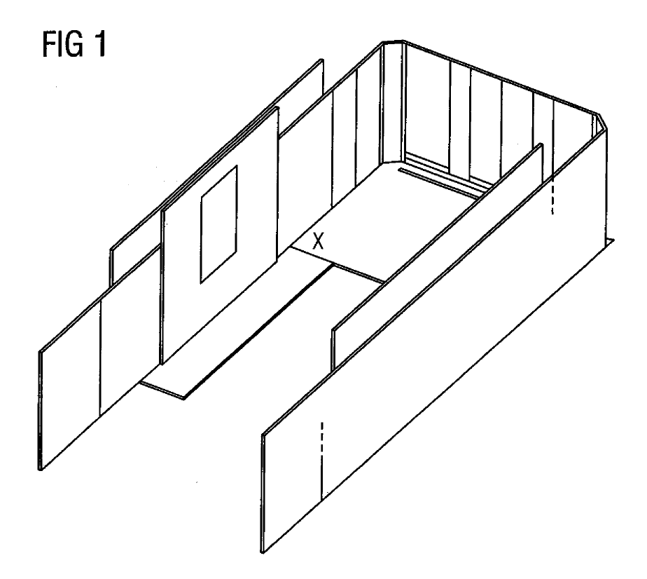

FIG. 2 illustrates a known screening arrangement according to the present invention for containing the stray field of a magnet used in a mobile MRI system; and

FIG. 3 illustrates magnetic induction (B-H) curves for materials as conventionally used, and as employed in an embodiment of the present invention.

### DESCRIPTION OF THE PREFERRED EMBODIMENTS

According to the present invention, at least part of the shielding of the truck of trailer is provided in a non-conventional material. Rather than the non-grain oriented, low carbon silicon steel used for magnetic screening in prior art arrangements, the present invention provides screening for high field magnets wherein at least part of the screening is composed of sheets of a grain-oriented steel, preferably a grain-oriented, low carbon, silicon steel, for example such as may be used in transformer core laminates. The inventors have found that such material has a higher magnetic induction B (at relatively low magnetic field strength H, and so provides improved shielding of stray fields of low magnetic flux density. A disadvantage in the use of such material is that it is more expensive than the conventional non-grain oriented, low carbon silicon steel.

A preferred embodiment of the present invention accordingly uses conventional non-grain oriented, low carbon silicon steel to provide the majority of the shielding, particularly in regions of high magnetic flux density, while the grain-oriented low carbon, silicon steel of the present invention is used to provide containment of the low magnetic flux density stray field. Such embodiment combines the low-cost and high flux density shielding properties of the non-grain oriented, low carbon silicon steel with the low flux density shielding properties of the grain oriented, low carbon silicon steel to provide an efficient shield for a reasonable cost, and reduced mass as compared to the shields of the prior art.

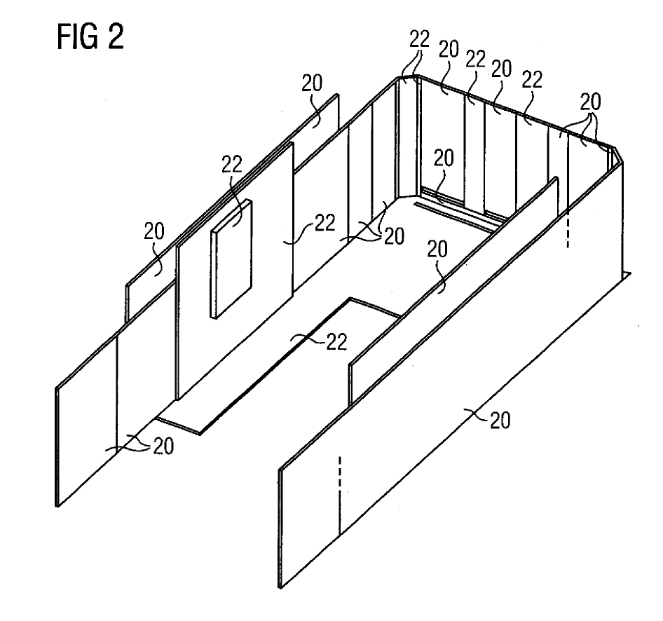

FIG. 2 shows a magnetic shielding arrangement for a magnet according to an embodiment of the present invention, in which the (shaded) layers 20 of the shield are constructed from sheets of the grain-oriented low carbon, silicon steel according to the invention, while other (un-shaded) layers 22 are constructed from conventional non-grain-oriented low carbon, silicon steel. Such layers appear in regions of high magnetic flux density, or in regions where increased mechanical strength is required, such as at the corners. Where the non-grain-oriented low carbon, silicon steel is provided for increased mechanical strength, it is typically provided in excess of an amount required for magnetic shielding. As illustrated in FIG. 2, it is preferred that the outermost layer of the magnetic shield should be formed of grain-oriented low carbon, silicon steel 20 according to the invention around the whole periphery of the shield, with conventional shielding layers 22 being provided within these layers 20 as required. This arrangement ensures that the layers 20 of grain-oriented low carbon, silicon steel according to the invention are used to provide efficient shielding of lower magnetic flux densities, while the conventional non-grain-oriented low carbon, silicon steel layers 22 are used to provide cost-effective and efficient shielding of higher applied magnetic fields.

This preferred embodiment has the advantage that the cheaper non-grain-oriented low carbon, silicon steel 22 is used to provide the majority of the shielding, yet the expensive grain-oriented low carbon, silicon steel 20 is only used to provide containment of low magnetic flux densities.

The magnetic shield of the present invention may be used with relatively high field magnets, that is, those which produce a magnetic field of flux density in excess of 1.5 T, with the advantage that the total weight of the trailer or truck does not exceed a maximum permissible value. Alternatively, the magnetic shield of the present invention may be used with magnets which produce a magnetic field of flux density 1.5 T or less, with the advantage that less steel need be used to provide shielding of the stray field, and the weight of the truck or trailer may be reduced, with commensurate cost savings in materials and fuel consumption.

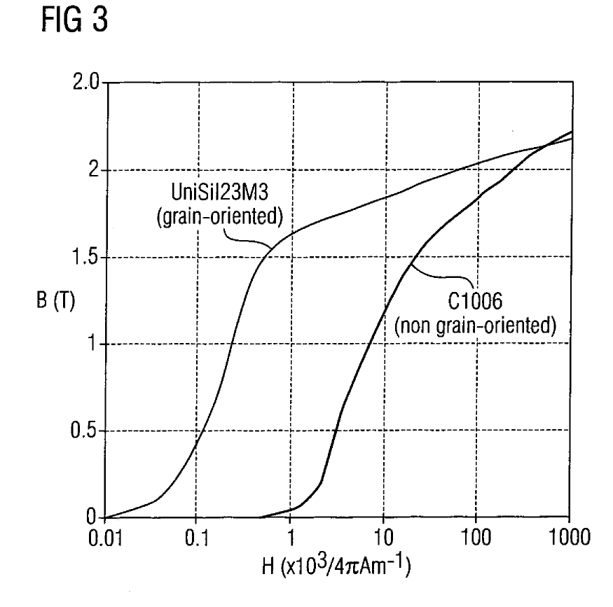

Current mobile trailer-mounted MRI systems designed by Siemens use a non-grain-oriented low carbon, silicon steel known as C1006 steel. In an embodiment of the present invention, the grain-oriented low carbon, silicon steel used is UniSil23M3, which is commonly used in transformer core laminates. FIG. 3 shows magnetic induction curves for these two materials. Other steels with similar structures and properties may be used as available. As can be clearly seen in FIG. 3, the grain-oriented UniSil23M3 has a magnetic flux density (B) at low applied field strength (H) which is significantly larger than that of the non-grain-oriented C1006 steel. This means that at low applied field strength, the grain-oriented UniSil23M3 is more efficient at containing a magnetic field of low magnetic flux density than the non-grain-oriented C1006, and so provides more efficient shielding of magnetic fields of low magnetic flux density. At higher applied magnetic field strengths, such as those in excess of 100 Oersted (100×10³/4π Am⁻¹), or above about 1 T magnetic flux density, the two materials behave in a similar fashion, both of them saturating at a flux density of about 1.6-1.8 T.

Some practical considerations must be taken into account when designing and building a magnetic shield according to the present invention. For example, the grain-oriented steel is non-isotropic. It functions efficiently when the magnetic field is aligned along the direction of the grains but it is less efficient when the field is perpendicular to the grains. In addition, the described grain-oriented steel is typically manufactured in thin sheets, of thickness 0.5 mm or less, which means that a large number of sheets may be required to provide the required shielding.

The described embodiment is believed to provide at least the following advantages. The composite shield, using both grain-oriented steel and non-grain-oriented steel, provides more efficient shielding than using either material in isolation. For a magnet producing a maximum flux density of over 1.5 T, more effective shielding is provided by the described composite shield since the most efficient material is used at high and low applied fields and the all-up weight of the shield is minimized. For a magnet producing a maximum flux density of less than about 1.5 T, a lighter-weight shield may be provided by the composite shield of the present invention, using both grain-oriented steel and non-grain-oriented steel, and so the all-up weight of the shield can be reduced compared to using either material in isolation. Reduction of the weight of the shield is particularly important in relation to mobile systems, although the invention could also be used to reduce the weight and volume of an iron or steel shield used in a static installation, such as in a building

The magnetic field produced by the shielded magnet may need to be shimmed to correct for distortions in the field caused by the shielding material. Several methods are known and understood by those skilled in the art for correcting such distortions. The provision of Z2 rings, rings of ferromagnetic material placed outside a cylindrical magnet, towards each end thereof, or body coil shims—typically pieces of steel strategically positioned within the body coils (also known as the RF coil)—may be found suitable.

A suitable alternative to UniSil23M3 is M6 Grain-Oriented Electrical Steel from ATI Allegheny Ludlum Corporation, 100 River Road Brackenridge, Pa. 15014, www.AlleghenyLudlum.com. Other grain oriented electrical steels are also available from this source.

While the present invention has been described with reference to certain particular materials, it will be apparent to those skilled in the art that other, equivalent materials may be used. Furthermore, while the invention relates to grain-oriented steels and non-grain oriented steels, other features of the example materials, such as the fact that they may contain silicon, or may have low carbon content, are not essential to the present invention. Similarly, while the present invention has been discussed with particular reference to shielding of mobile MRI systems, the invention may be applied to the shielding of magnetic fields generated by other equipment, and to fixed or mobile systems, whether related to MRI imaging or not.

Although other modifications and changes may be suggested by those skilled in the art, it is the intention of the inventors to embody within the patent warranted hereon all changes and modifications as reasonably and properly come within the scope of their contribution to the art.

We claim as our invention:

1. Magnetic shielding for surrounding a magnet generating a magnetic field of maximum magnetic flux density substantially in excess of 5 Gauss (5×10⁻⁴ T), so as to reduce the magnetic flux density outside the shielding to no more than 5 Gauss (5×10⁻⁴ T), comprising a portion of the shielding being comprised of sheets of grain-oriented steel, and another portion of the shielding being composed of sheets of non-grain-oriented steel, in which layers of said sheets of non-grain-oriented steel are located in regions of relatively high magnetic flux density, and in which only layers said sheets of grain-oriented steel are located in regions of relatively low magnetic flux density.

2. Magnetic shielding according to claim 1 surrounding a magnet generating a magnetic field of maximum magnetic flux density in excess of 0.5 T.

3. Magnetic shielding according to claim 2 surrounding a magnet generating a magnetic field of maximum magnetic flux density in excess of 1.0 T.

4. Magnetic shielding according to claim 3 surrounding a magnet generating a magnetic field of maximum magnetic flux density in excess of 1.5 T.

5. Magnetic shielding according to claim 1 surrounding a magnet generating a magnetic field of maximum magnetic flux density in excess of 3 T.

6. Magnetic shielding according to claim 1, wherein a majority of the shielding is composed of said sheets of non-grain-oriented steel.

7. Magnetic shielding according to claim 1, comprising additional non-grain-oriented steel in regions where increased mechanical strength is required.

8. Magnetic shielding according to claim 1, comprising an outermost layer of the magnetic shielding formed of grain-oriented steel around an entire periphery of the shield, also with layers of said sheets of non-grain-oriented steel being provided within the outermost layer.

9. Magnetic shielding according to any claim 1, wherein the non-grain-oriented steel is C1006 steel.

10. A mobile magnetic resonance imaging apparatus comprising:
a magnetic resonance imaging apparatus comprising a magnet that generates a magnetic field of a maximum magnetic flux density substantially in excess of 5 Gauss;
a mobile carrier on which said magnetic resonance imaging apparatus is mounted; and
magnetic shielding that surrounds said magnet so as to reduce the magnetic flux density outside the shielding to no more than 5 Gauss, a portion of the shielding being comprised of sheets of grain-oriented steel, and another portion of the shielding being composed of sheets of non-grain-oriented steel, in which layers of said sheets of non-grain-oriented steel are located in regions of relatively high magnetic flux density, and in which only layers said sheets of grain-oriented steel are located in regions of relatively low magnetic flux density.

11. A mobile magnetic resonance imaging apparatus comprising:
a magnetic resonance imaging apparatus comprising a magnet that generates a magnetic field of a maximum magnetic flux density substantially in excess of 5 Gauss; and
magnetic shielding that surrounds said magnet so as to reduce the magnetic flux density outside the shielding to no more than 5 Gauss, a portion of the shielding being comprised of sheets of grain-oriented steel, and another portion of the shielding being composed of sheets of non-grain-oriented steel, in which layers of said sheets of non-grain-oriented steel are located in regions of relatively high magnetic flux density, and in which only layers said sheets of grain-oriented steel are located in regions of relatively low magnetic flux density.
